(19) United States
(12) Patent Application Publication
(10) Pub. No.: US 2024/0321907 A1
(43) Pub. Date: Sep. 26, 2024

(54) ARRAY SUBSTRATE AND DISPLAY DEVICE

(71) Applicant: XIAMEN TIANMA DISPLAY TECHNOLOGY CO., LTD., Xiamen (CN)

(72) Inventor: Yongxiang LIN, Xiamen (CN)

(73) Assignee: XIAMEN TIANMA DISPLAY TECHNOLOGY CO., LTD., Xiamen (CN)

(21) Appl. No.: 18/733,902

(22) Filed: Jun. 5, 2024

(30) Foreign Application Priority Data
Dec. 29, 2023 (CN) 202311872232.1

(51) Int. Cl. H01L 27/12

(52) U.S. Cl. CPC H01L 27/1244

(57) ABSTRACT

An array substrate and a display device are provided. The array substrate includes a substrate, a first metal layer, a second metal layer and a semiconductor layer. The first metal layer is located on a side of the semiconductor layer away from the substrate. The first metal layer includes first wiring. The semiconductor layer includes second wiring. The second metal layer includes jumper wiring. The array substrate includes an active area and a non-active area. In the non-active area, the second wiring includes a first segment and a second segment located on both sides of the first wiring respectively in a first direction, and connected through the jumper wiring. In a direction perpendicular to a plane in which the array substrate extends, the jumper wiring at least partially overlaps the second wiring.

### CROSS-REFERENCE TO RELATED APPLICATION

This application claims priority to Chinese Patent Application No. 202311872232.1, titled “ARRAY SUBSTRATE AND DISPLAY DEVICE”, filed on Dec. 29, 2023 with the China National Intellectual Property Administration, which is hereby incorporated by reference in its entirety.

### FIELD

The present disclosure relates to the field of display technology, and in particular to an array substrate and a display device.

### BACKGROUND

A display panel, as an important part of a display device, is configured to realize the display function of the display device. An organic light-emitting diode (OLED) display panel has been widely applied in many scenarios because of advantages of self-illumination, high saturation, high luminous efficiency, short response time, and flexible display.

Users impose increasingly high requirements for pixel density and frame width of display products as the display technology advances. The display panel includes a semiconductor layer, multi-layer metal, and multiple insulating layers. Each layer has a pattern. Due to a dense arrangement of signal wires in the display panel, semiconductor wires and metal wires may overlap in some regions, which affects the transmission of electrical signals, causing dark lines and other undesirable phenomena to occur in partial regions of the display panel, resulting in poor display results.

### SUMMARY

An array substrate and a display device are provided according to embodiments of the present disclosure. The above problem or at least a part of the above problem is solved.

An array substrate is provided according to the present disclosure. The array substrate includes a substrate, a first metal layer, a second metal layer and a semiconductor layer; where the first metal layer is located on a side of the semiconductor layer away from the substrate; the first metal layer includes first wiring, the semiconductor layer includes second wiring, and the second metal layer includes jumper wiring; the array substrate includes an active area and a non-active area; in the non-active area, the second wiring includes a first segment and a second segment, which are connected by the jumper wiring, the first segment is located on one side of the first wiring in a first direction, the second segment is located on another side of the first wiring in the first direction; the jumper wiring at least partially overlaps the second wiring in a direction perpendicular to a reference plane, in which the array substrate extends.

A display device is further provided according to embodiments of the present disclosure, including the above array substrate.

### BRIEF DESCRIPTION OF THE DRAWINGS

Drawings, which are incorporated in and constitute a part of this specification, illustrate embodiments according to the present disclosure and serve to elaborate principles of the present disclosure together with the specification.

In order to illustrate the embodiments of the present disclosure clearly, the drawings needed to be used in the description of the embodiments are briefly introduced below.

FIG. 1A is an overall schematic diagram of an array substrate in a related art.

FIG. 1B is an enlarged schematic diagram of a fillet area of an array substrate in FIG. 1A.

FIG. 1C is a schematic cross-sectional view along X-X′ in FIG. 1B.

FIG. 1D is a schematic effect diagram of a test screen of the fillet area of the array substrate in FIG. 1A.

FIG. 2 is a schematic cross-sectional view of an array substrate according to an embodiment of the present disclosure.

FIG. 3 is a schematic plan view of an array substrate according to an embodiment of the present disclosure.

FIG. 4A is a schematic cross-sectional view of an array substrate according to another embodiment of the present disclosure.

FIG. 4B is a schematic plan view of a non-active area of an array substrate according to another embodiment of the present disclosure.

FIG. 5 is a schematic plan view of an array substrate according to another embodiment of the present disclosure.

FIG. 6 is a schematic cross-sectional view of an array substrate according to another embodiment of the present disclosure.

FIG. 7 is a schematic cross-sectional view of an array substrate according to another embodiment of the present disclosure.

FIG. 8 is a schematic plan view of a non-active area of an array substrate according to an embodiment of the present disclosure.

FIG. 9 is an overall schematic diagram of an array substrate according to an embodiment of the present disclosure.

FIG. 10 is a schematic cross-sectional view of an array substrate according to another embodiment of the present disclosure.

FIG. 11 is a schematic cross-sectional view of an array substrate according to another embodiment of the present disclosure.

FIG. 12 is a schematic cross-sectional view of an array substrate according to another embodiment of the present disclosure.

FIG. 13 is a schematic cross-sectional view of an array substrate according to another embodiment of the present disclosure.

FIG. 14 is a schematic cross-sectional view of an array substrate according to another embodiment of the present disclosure.

### DETAILED DESCRIPTION

In order to understand the embodiments of the present disclosure clearly, the solutions of the present disclosure are further described below. It should be noted that, the embodiments of the present disclosure and the features in the embodiments may be combined with each other as long as there is no conflict.

Many specific details are set forth in the following description to fully understand the present disclosure, and the present disclosure may also be implemented in other ways different from those described here. Apparently, embodiments in the description are only part, not all of the embodiments of the present disclosure.

It is understood that when a component or layer is referred to as being “on”, “one side of” or “connected to” another component, the two components may be directly connected or may have other components located between them.

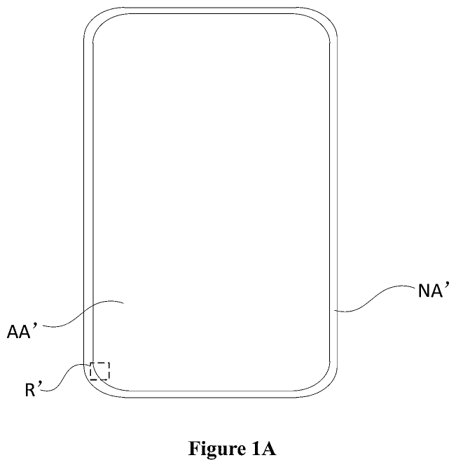

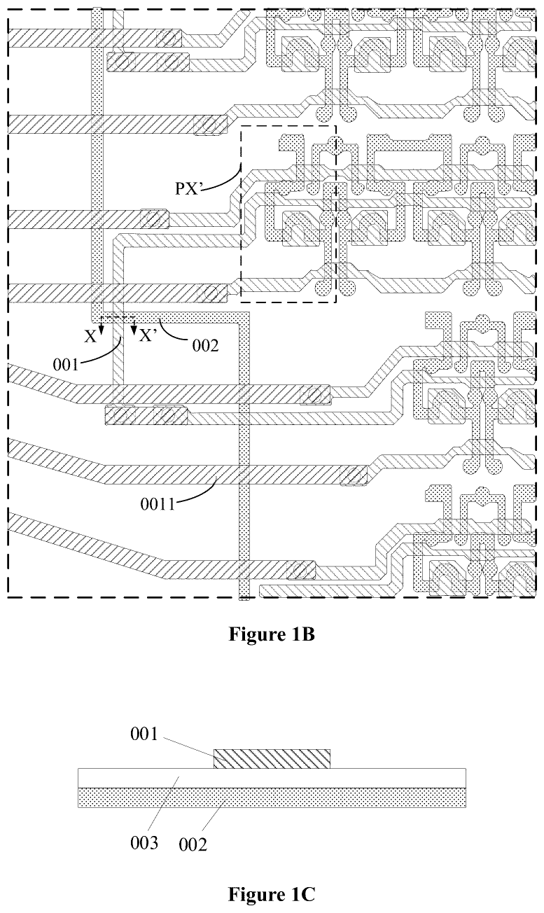

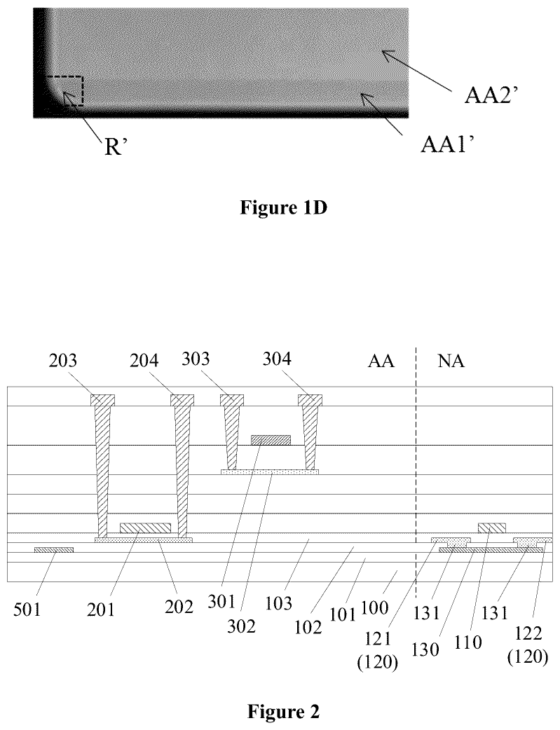

Reference is made to test results shown in FIG. 1D. In a case that a screen of a display panel is tested, an obvious horizontal dark lines appear in a first active area AA′ of the display panel in comparison with a second active area AA2′. The first active area AA1′ showing dark lines corresponds to R′ area of the display panel. Reference is made to FIGS. 1A to 1D, many users begin to pursue full-screen display with widespread use of the display panel. The display panel usually includes semiconductor layers, multiple metal layers and multiple insulating material layers, and each layer of material has a pattern. Multiple patterns of the semiconductor layers usually include some semiconductor patterns configured as active layers of thin film transistors, and some semiconductor wires configured for signal transmission. The resistivity of the semiconductor wires, configured for signal transmission, is generally smaller than the resistivity of the semiconductor patterns which are the active layers of the thin film transistors. In some regions of the display panel, due to layout restrictions or other reasons, the semiconductor wires 002 overlaps the metal wires 001. Reference is made to FIG. 1B, which shows a part of film structures of the display panel and circuits in order to highlight the relationship between the semiconductor layer and its adjacent metal wires 001. Herein the display panel may further include some other metal films and insulating layers. In some cases, both ends of the metal wire 001 are respectively electrically connected to two rows of pixel circuits PX′ in the active area. Two adjacent rows of pixel circuits PX′ receive a same signal, which may save the number of signal wirings in the display panel. In some cases, the metal wire 001 may be electrically connected to the pixel circuit PX′ in the active area AA′ of the display panel. The metal wire 001 may also be connected to peripheral circuits (not shown in the figure) in the non-active area NA′ to transmit signals from the peripheral circuits to the pixel circuits in the active area AA′. Although the semiconductor wire 002 and the metal wire 001 are separated by the insulating layer 003, since the metal wire 001 covers at least a part of the semiconductor wire 002 in a direction perpendicular to a plane of the display panel, the part of the semiconductor wire 002 covered by the metal wire 001 cannot reach an ideal doping state in the process of ion doping the semiconductor to make the semiconductor conductive, to affect the conductivity of the semiconductor wire 002 and causing that the conductivity of the part of the semiconductor wire 002 covered by the metal wire 001 is greatly different from that of another part of the semiconductor wire 002 not covered by the metal wire 001. In a case that the signal on the semiconductor wire 002 is transmitted to the overlap between the semiconductor wire 002 and the metal wire 001, undesirable phenomena, such as dark lines, is easy to occur in local regions of the display panel, resulting in problems with poor display. It may be equivalent to forming a thin film transistor device at the overlap of the metal wire 001 and the semiconductor wire 002.

In response to the above problems, an array substrate and a display device are according to embodiments of the present disclosure, which can avoid the impact of the metal wire on the conductivity of the semiconductor wire, to avoid undesirable phenomena such as dark lines and solving the problem of poor display.

The array substrate and display device according to embodiments of the present disclosure are exemplarily described below with reference to the accompanying drawings.

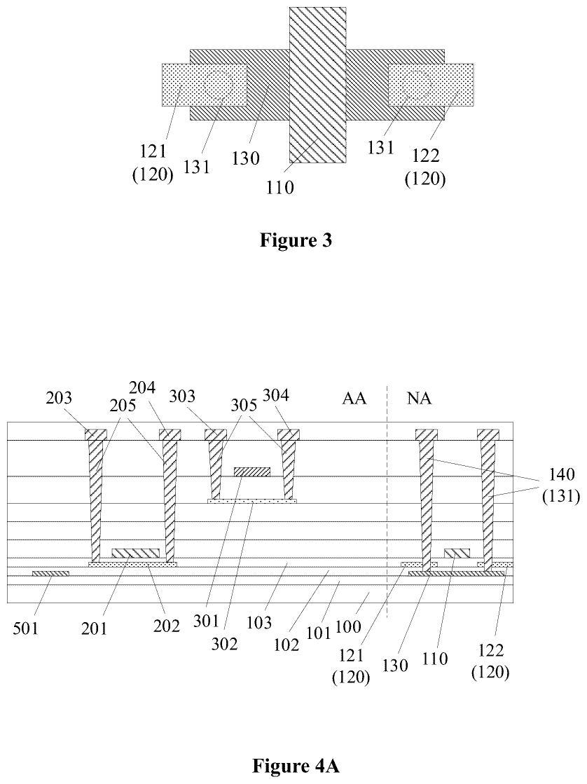

Reference is made to FIGS. 2 and 3. FIG. 2 is a schematic cross-sectional view of an array substrate according to an embodiment of the present disclosure. FIG. 3 is a schematic plan view of an array substrate according to an embodiment of the present disclosure. Herein the array substrate includes layer structures such as a substrate 100, a first metal layer, a second metal layer and a semiconductor layer. The first metal layer is located on a side of the semiconductor layer away from the substrate. The first metal layer includes first wiring 110, the semiconductor layer includes second wiring 120, and the second metal layer includes a jumper wiring 130.

The array substrate includes an active area AA and a non-active area NA. In the non-active area, the second wiring 120 extends in a first direction. The second wiring 120 includes a first segment 121 and a second segment 122. The first segment 121 and the second segment 122 are respectively located on both sides of the first wiring 110 in the first direction. The first segment 121 and the second segment 122 are connected by the jumper wiring 130. The jumper wiring 130 at least partially overlaps the second wiring 120 in the direction perpendicular to a reference plane, in which the array substrate extends.

Herein the second wiring 120 of the semiconductor layer is divided into a first segment 121 and a second segment 122 in the array substrate, to avoid that the first wiring 110 of the first metal layer overlaps the second wiring 120. Then the first segment 121 and the second segment 122 of the second wiring 120 are connected by the jumper wiring 130 of the second metal layer, and the second wiring 120 may transmit electrical signals through the first segment 121, the jumper wiring 130, and the second segment 122. Although the first wiring 110 overlaps the jumper wiring 130, both are metal and may not affect each other's conductivity. Herein, the array substrate can prevent the first wiring 110 from affecting the conductivity of the second wiring 120, to avoid undesirable phenomena such as dark lines and solving the problem of poor display.

In some embodiments, the array substrate further includes an insulating layer 102 between the semiconductor layer and the second metal layer. A via 131 is formed through the insulating layer 102. The first segment 121 and the second segment 122 of the second wiring 120 are connected to the jumper wiring 130 through the via hole 131. In the process of manufacturing the array substrate, after forming the jumper wiring 130, the insulating layer is etched to form the via hole, then a pattern of the second wiring 120 is formed, and the first segment 121 and the second segment 122 of the second wiring 120 fill the via hole and are connected to the jumper wiring 130, and the second wiring 120 may transmit electrical signals through the first segment 121, the jumper wiring 130, and the second segment 122.

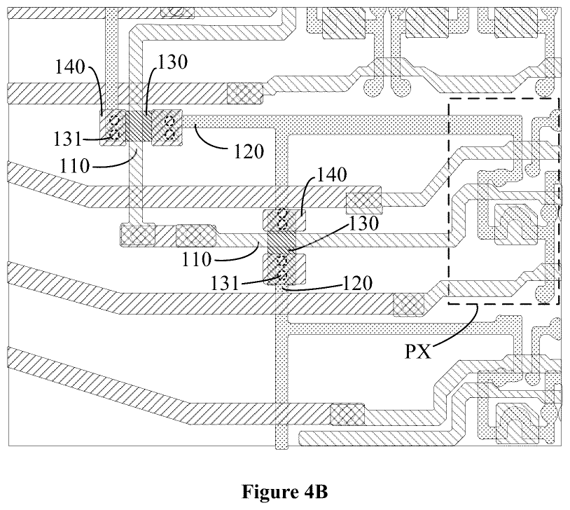

In some embodiments, as shown in FIGS. 4A-B and 5, FIG. 5 is a schematic plan view of an array substrate according to another embodiment of the present disclosure. The array substrate further includes a third metal layer. The third metal layer includes a jumper column 140 filled in the via hole. The first segment 121 and the second segment 122 of the second wiring 120 are connected to the jumper wiring 130 through the jumper column 140.

In the process of manufacturing the array substrate, multiple patterns of the metal layer need to be prepared. Before preparing the third metal layer, multiple via holes for the pixel circuit need to be etched. The via holes 131 configured to form the jumper columns 140 may be etched and formed simultaneously with the via holes for the pixel circuit. There is no need to add additional etching steps for the via holes 131, to maintain the production efficiency of the array substrate.

In some embodiments, a pixel circuit is disposed in the active area and includes a gate electrode 201, a semiconductor 202, a source electrode 203 and a drain electrode 204 of a first transistor, and a gate electrode 301, a semiconductor 302, a source electrode 303 and a drain electrode 304 of a third transistor. The third metal layer includes source electrodes 203, 303 and drain electrodes 204, 304. The source electrode 203 and the drain electrode 204 are connected to the semiconductor 202 through the via hole 205. The source electrode 303 and the drain electrode 304 are connected to the semiconductor 302 through the via hole 305. The via holes 131 configured to form the jumper columns 140 may be etched and formed simultaneously with the via holes 205 and 305. There is no need to add additional etching steps for the via holes 131, to maintain the production efficiency of the array substrate.

In some embodiments, the source and drain electrodes of the transistors may be in different metal layers. Hence the third metal layer, including the jumper columns, may include only one of the source electrode and the drain electrode of the first transistor, or only one of the source electrode and the drain electrode of the third transistor.

In some embodiments, as shown in FIG. 4B, some structures and films of the display panel are omitted in FIG. 4B, in order to highlight the relationship between the semiconductor wire 120, the metal wire 110 and the jumper wiring 130. The first metal layer is a gate metal layer. The array substrate further includes a third metal layer. The third metal layer includes the jumper columns 140 filled in the via holes. The second wiring 120, located on both sides of the first wirings 110, is connected to the jumper wiring 130 through the jumper columns 140. The jumper columns 140 may be electrically connected to the second wiring and the jumper wiring 130 through the via holes 131 respectively. In other words, one end of the jumper column 140 is electrically connected to one end of the second wiring 120 (e.g., the first segment 121) through the via hole 131. The other end of the jumper column 140 is electrically connected to one end of the jumper wiring 130 through the via hole 131, and the electrical connection between the second wiring 120 and one end of the jumper wiring 130 is implemented. The other end of the jumper wiring 130 may also be electrically connected to the other end of the second wiring (e.g., the second segment 122) in a same manner. With such design, in the process of manufacturing wires in the third metal layer, the wires are manufactured together with the process of filling metal in other metal via holes of the pixel circuit PX in the display panel, and the process cost may be saved.

In some embodiments, the semiconductor layer including the second wiring 120 is a silicon semiconductor layer, for example, the low temperature poly-silicon (LTPS). Semiconductors are mainly divided into two categories: silicon semiconductors and oxide semiconductors. Herein the problems to be solved are mainly in situations of silicon semiconductors. Since a resistance value of polysilicon in LTPS is large, implanting ions may be configured to change the conductive carrier concentration in the silicon semiconductor, in order to improve the conductivity of the second wiring 120 located in the semiconductor layer to achieve signal transmission. That is, the semiconductor is made to be conductive. In a related art, reference is made to FIGS. 1A-C. In the process of manufacturing the array substrate, after forming the semiconductor wire 002 of LTPS, the insulating layer, and the metal wire 001 in the above-listed sequence, the semiconductor structure configured as the signal wires needs to be ion-doped. That is, the semiconductor wire 002 needs to be ion-doped to increase carrier concentration and reduce the resistivity of the silicon semiconductor in the semiconductor wire 002, and the LTPS semiconductor in the semiconductor wire 002 is doped from a semiconductor to a conductor. The process of ion doping the semiconductor wires 002 in the semiconductor layer to improve its conductivity is usually performed after the process of manufacturing a gate metal layer of the display panel. In the process of manufacturing the display panel, after the substrate is provided, a semiconductor layer may be formed on the substrate and patterned. Then an insulating layer 003 may be formed on the semiconductor layer and patterned based on design requirements. Then a gate metal layer may be formed on the insulating layer 003. After manufacturing the gate metal layer, some structures in the semiconductor layer are ion-doped to intensify its conductivity. In the direction perpendicular to the reference plane, the semiconductor wire 002 includes a portion that overlaps the metal wire 001. The metal wire 001 is above the segment 004 of the semiconductor wire 002, hence the metal wire 001 may block doped ions, and a part of the semiconductor wire located below the metal wire 001 is free of doped ions, causing the carrier concentration in this part of the silicon semiconductor material to be very low. The conductivity of this part of the silicon semiconductor material is much worse than the conductivity of other parts of the semiconductor wire 002. When an electrical signal is transmitted to the part of the semiconductor wire 002 that overlaps the metal wire 001, the resistance of the semiconductor wire 002 may suddenly change since the portion of the semiconductor wire 002 is free of doped ions, resulting in failure of normal transmission of electrical signals, causing dark lines or other undesirable phenomena in local regions of the display panel, leading to problems with poor display.

Herein, the second wiring 120 in the silicon semiconductor layer is divided into a first segment 121 and a second segment 122, which are connected by the jumper wiring 130 that is made of a metal material. Thus, in a case of performing ion doping on the second wiring 120, only the first segment 121 and the second segment 122 need to be ion-doped. The jumper wiring 130, between the first segment 121 and the second segment 122, is made of metal material, which has good electrical conductivity and does not require ion doping, which is not affected by the first wiring 110 in the process of manufacturing the display panel, to avoid a negative impact of the first wiring 110 on the ion doping of the second wiring 120 of the silicon semiconductor. The second wiring 120 may transmit electrical signals normally through the jumper wiring 130, avoiding the occurrence of undesirable phenomena such as dark lines, and solving the problem of poor display.

In some embodiments, some wires may be formed using oxide semiconductors, hence the semiconductor layer including the second wiring 120 may be an oxide semiconductor, such as indium gallium zinc oxide (IGZO). As shown in FIG. 4A, the pixel circuit in the array substrate uses low temperature polycrystalline oxide (LTPO) technology. That is, the pixel circuit includes two semiconductors, LTPS and IGZO. The semiconductor 302 of the third transistor is an oxide semiconductor.

In some embodiments, as shown in FIG. 4A, the second metal layer, where the jumper wiring 130 is located, is located between the substrate 100 and the semiconductor layer in a direction perpendicular to the reference plane. A buffer layer 101 is formed on the substrate 100 of the array substrate, a second metal layer is located on the buffer layer 101, the second metal layer is covered with an insulating layer 102, and the semiconductor layer is located on the insulating layer 102. The second metal layer is a bottom layer and achieves functions such as light shielding and signal conduction by forming patterns. In the process of manufacturing the array substrate, the jumper wiring 130 may be formed simultaneously with other patterns of the second metal layer. An additional etching step is not required for the jumper wiring 130, to maintain the production efficiency of the array substrate.

In some embodiments, as shown in FIG. 4A, the active area of the display panel may further include an optical component setting area such as a fingerprint identification area or an under-screen camera setting area. The second metal layer includes a light-shielding pattern 501 formed in the optical component setting area. The optical component setting area being the fingerprint identification area is taken as an example. In display devices such as smartphones and tablets, a fingerprint identification area, configured for user fingerprint authentication, is a part of the active area. The light-shielding pattern 501 may prevent light leakage when the user performs fingerprint authentication. In the process of manufacturing the array substrate, the jumper wiring 130 may be formed simultaneously with the light-shielding pattern 501. An additional etching step for the jumper wiring 130 is not required, to maintain the production efficiency of the array substrate. In an embodiment, when the optical component setting area is the under-screen camera setting area, the light-shielding pattern 501 overlaps multiple signal wires (not shown in the drawings) in the under-screen camera setting area to block gaps between signal wires. Diffraction may be avoided in a case that light passes through the gaps between signal wires, which affects the imaging effect of the under-screen camera.

In some embodiments, the first metal layer is a gate metal layer, as shown in FIG. 4A, the first metal layer further includes the gate electrode 201 of the first transistor in addition to the first wiring 110. When the first wiring 110 is in a same layer as the gate electrode of the first transistor, a part semiconductor structure (e.g. the second wiring) in the semiconductor layer may be ion-doped after a process of manufacturing the gate electrode in the process of manufacturing display panel. In a case that a semiconductor structure that requires ion doping is beneath the first wiring 110, the semiconductor structure is made to be conductive by the ion doping, which is affected inevitably by the first wiring 110. Thus, expected effect may not be achieved. In an embodiment, in the direction perpendicular to the reference plane, the second wiring 120 includes a first segment 121 and a second segment 122 located on both sides of the first wiring 110 and not overlapping the first wiring 110. Then, the first segment 121 and the second segment 122 are respectively connected through the jumper wiring 130, and the second wiring 120 may transmit electrical signals normally, avoiding problems of partial dark lines on the display panel caused by the sudden change in resistance on the second wiring 120.

In some embodiments, the active area includes a pixel circuit. As shown in FIG. 5, the pixel circuit includes a first transistor. A first end of the first wiring 110 is electrically connected to the gate electrode 201 of the first transistor. The non-active area includes a first gate driving circuit G1. A second end of the first wiring 110 is electrically connected to an output terminal of the first gate driving circuit. The first wiring 110, as a gate signal wiring, connects the first gate driving circuit G1 in the non-active area and the gate electrode 201 of the first transistor in the active area, to transmit a gate driving signal output by the first gate driving circuit G1 to the gate electrode 201. The first wiring 110 as the gate signal wiring often overlaps the second wiring 120. The jumper wiring 130 and the jumper column 140 are configured to connect the first segment 121 and the second segment 122 of the second wiring 120, avoiding the negative impact of the first wiring 110 on the ion doping of the second wiring 120 made of the silicon semiconductor. The second wiring 120 is capable of transmitting electrical signals normally through the jumper wiring 130, avoiding the occurrence of undesirable phenomena such as dark lines, solving the problem of poor display effect.

In some embodiments, as shown in FIG. 4A and FIG. 5, a minimum distance w1 between the first segment 121 and the second segment 122 is greater than a width w2 of the first wiring 110 in the first direction, which may ensure that the second wiring 120 does not overlap the first wiring 110, which avoids the influence of the first wiring 110 on the ion doping of the second wiring 120 effectively. The length of the jumper wiring 130 is also increased accordingly. The jumper wiring 130 made of metal material has excellent conductivity and can improve an overall conductivity of the second wiring 120.

In some embodiments, the width of the first wiring 110 ranges from 2 μm to 3 μm, and the minimum distance between the first segment 121 and the second segment 122 ranges from 4 μm to 6 μm, and a distance between the first segment 121 and the first wiring 110 may ranges from 1 μm to 2 μm, and a distance between the second segment 122 and the first wiring 110 also ranges from 1 μm to 2 μm to avoid the influence of the first wiring 110 on the ion doping of the second wiring 120.

In some embodiments, the minimum distance between the first segment 121 and the second segment 122 may be less than or equal to the width of the first wiring 110.

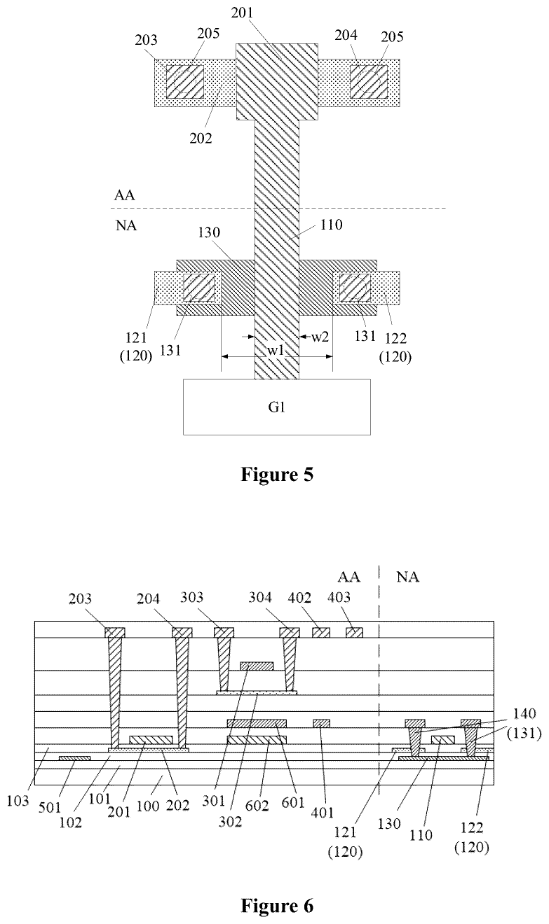

In some embodiments, reference is made to FIG. 6, which is a schematic cross-sectional view of an array substrate according to another embodiment of the present disclosure. The active area includes a pixel circuit, the pixel circuit includes a first power voltage signal wiring 401 and a data signal wiring 402. The third metal layer includes the first power voltage signal wiring 401. In addition, the pixel circuit in the active area further includes a storage capacitor. In the direction perpendicular to the reference plane, an upper electrode plate 601 of the storage capacitor is located on a same layer as the first power voltage signal wiring 401 and the jumper column 140. A lower plate is located on the first metal layer and is located on a same layer as the first wiring 110 and the gate electrode 201. The pixel circuit may further include a second power voltage signal wiring 403. The second power voltage signal wiring 403 and the first power voltage signal wiring 401 are in different layers and have different extending directions. The second power voltage signal wiring 403 is electrically connected to the first power voltage signal wiring 401 to form a mesh structure.

In the process of manufacturing the array substrate, before preparing the third metal layer, the insulating layer 103 is etched to form the via hole 131. Then the pattern of the third metal layer, the upper electrode plate 601 and the jumper column 140 are formed. The first segment 121 and the second segment 122 of the second wiring 120 are connected to the jumper wiring 130 through the jumper column 140. In this embodiment, the via hole 131 and the jumper column 140 have a small depth, which have a small impedance, which are beneficial to transmitting electrical signals between the second wiring 120 and the jumper wiring 130.

In some embodiments, the power voltage signal wiring and the data signal wiring may be located in different metal layers, hence the third metal layer including the jumper column may include only one of the power voltage signal wiring and the data signal wiring.

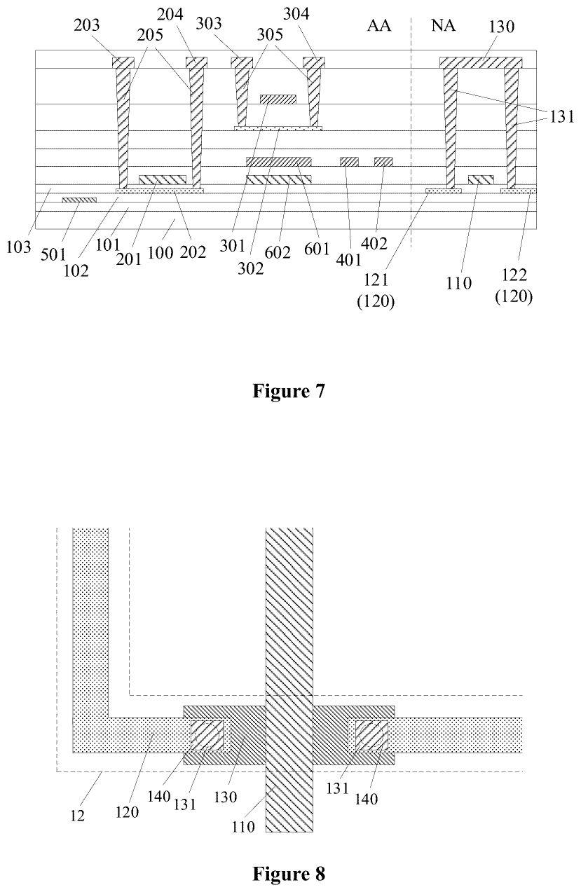

In some embodiments, reference is made to FIG. 7, which is a schematic cross-sectional view of an array substrate according to another embodiment of the present disclosure. The first metal layer and the semiconductor layer are located between the second metal layer and the substrate. That is, the jumper wiring 130 is located above the first wiring 110. The jumper wiring 130, the source electrodes 203, 303, and the drain electrodes 204, 304 are arranged on a same layer. In the process of manufacturing the array substrate, the via holes 131, 205, and 305 may be etched and formed simultaneously, then the jumper wiring 130 may be directly connected to the first segment 121 and the second segment 122 of the second wiring 120. An additional etching step is not required for the via hole 131, to maintain the production efficiency of the array substrate. In other embodiments, the jumper wiring 130, the voltage signal wiring 401, the data signal wiring 402, and the upper electrode plate 601 may be arranged in a same layer.

In some embodiments, reference is made to FIG. 8, which is a schematic plan view of a non-active area of an array substrate according to an embodiment of the present disclosure. The semiconductor layer includes an electrostatic ring 12 that at least partially surrounds the active area. The electrostatic ring 12 includes the second wiring 120. Only a small part of the electrostatic ring 12 is shown in FIG. 8. The resistance of the semiconductor layer itself is relatively large. The process of manufacturing the array substrate, after manufacturing the semiconductor layer, further includes some other processes, such as cleaning and ashing, especially in processes of which, static electricity is accumulated in the semiconductor layer. In a case that the static electricity may not be released in time, discharging and other phenomena may occur, causing damage to the structure and performance of the semiconductor layer, thus affecting the performance of the corresponding thin film transistor and causing uneven display on the display panel. Therefore, the applicant connects the semiconductor layer patterns in the active area together in the layout design, then connects them to the peripheral wiring located in the non-active area to form an electrostatic ring 12 surrounding the entire active area or a part of the active area. The static electricity, locally accumulated, is evenly distributed and released to the periphery to ensure uniform characteristics of the thin film transistors in the display panel and avoid display differences in local areas of the display panel caused by performance damage to some thin film transistors.

Since the electrostatic ring 12 surrounds the entire active area or a part of the active area, many electrical signals in the active area are to be introduced from the non-active area through wires, such as gate driving signals, power voltage signals, data signals, or the like. Hence the electrostatic ring 12 often overlaps other metal wires. Reference is made to FIG. 8. In order to prevent the second wiring 120 from overlapping the first wiring 110 in the electrostatic ring 12, the jumper wiring 130 and the jumper column 140 are configured to connect the first segment 121 and the second segment 122 of the second wiring 120, to avoid the negative impact of the first wiring 110 on the ion doping of the second wiring 120.

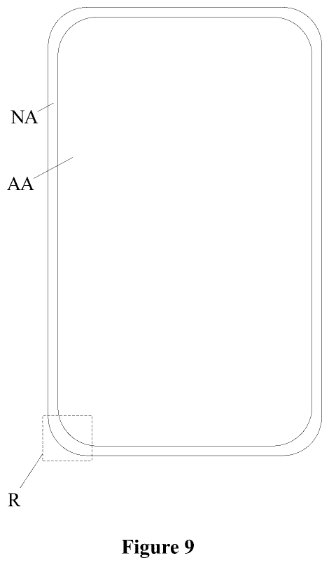

In some embodiments, reference is made to FIG. 9, which is an overall schematic diagram of an array substrate according to an embodiment of the present disclosure. The non-active area includes a fillet area R, the fillet area R includes a curved edge. The fillet area R includes the second wiring. More and more rounded corner designs are adopted in the display devices such as smartphones, smart watches, and tablet computers. The active area AA and the non-active area NA of these display devices includes fillet area areas R with curved edges. The above-mentioned overlap between the electrostatic ring and the metal wires exists inevitably in the fillet area R. Moreover, the wiring in the fillet area R is much dense and complex. Each pattern layer in the fillet area R is arranged with wires with different functions, for example, fan-out wires, power voltage signal bus that transmits power voltage signals from flexible circuit boards to the active area, or the like.

Therefore, the metal wires, which overlap the electrostatic ring in the fillet area R, are more difficult to lead out across layers to avoid affecting the ion doping of the electrostatic ring. In an embodiment, the second metal layer, located between the semiconductor layer and the substrate, is configured to form the jumper wiring. The negative impact of the first wiring on the ion doping of the second wiring may be avoided under the condition of dense and complex wiring in the fillet area R. Thus, the second wiring may transmit electrical signals normally through the jumper wiring, avoiding the occurrence of undesirable phenomena such as dark lines and solving the problem of poor display effects.

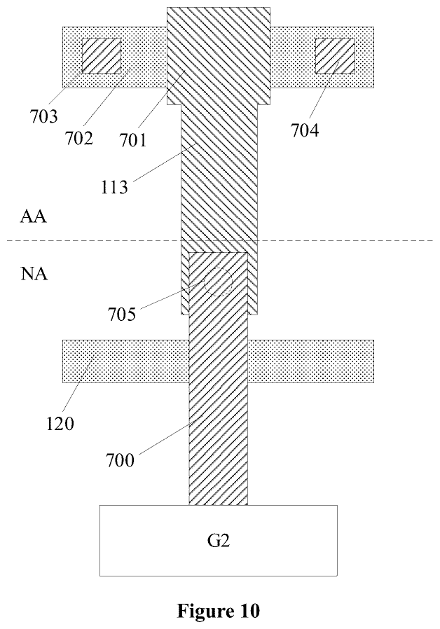

In some embodiments, reference is made to FIG. 10, which is another schematic cross-sectional view of an array substrate according to an embodiment of the present disclosure. The array substrate further includes a third metal layer and an insulating layer located between the first metal layer and the third metal layer. The third metal layer is located on a side of the first metal layer away from the semiconductor layer. That is, the third metal layer is located above the first wiring 110.

The non-active area NA further includes a straight-edge area (non-fillet). The straight-edge area includes straight edges. The straight-edge area includes a second gate driving circuit G2 and peripheral lead wiring 700 located on the third metal layer. The first metal layer includes third wiring 113.

The active area AA includes a pixel circuit, which includes a second transistor. The second transistor includes a gate electrode 701, a semiconductor 702, a source electrode 703, and a drain electrode 704. The third wiring 113 is electrically connected to the gate electrode 701 of the second transistor. The peripheral lead wiring 700 connects the third wiring 113 and the second gate driving circuit G2. A via hole 705 is formed in the insulating layer (not shown in the figure). The peripheral lead wiring 700 is connected to the third wiring 113 through the via hole 705. The via hole 705 is located on a side of the second wiring 120 close to the active area AA. The peripheral lead wiring 700 and the second wiring 120 overlap at least partially in a direction perpendicular to the reference plane.

The straight edge of the straight-edge area has more ample space than the arc edge of the fillet area. In order to prevent the third wiring 113 of the first metal layer from affecting the ion doping of the second wiring 120 of the semiconductor layer, the upper third metal layer is configured to set the peripheral lead wiring 700. The via hole 705 is connected to the third wiring 113, and the gate driving signal output by the second gate driving circuit G2 is transmitted to the gate electrode 701 of the second transistor through the peripheral lead wiring 700 and the third wiring 113. Because the third metal layer is located above the first metal layer, the process of manufacturing the third metal layer is relatively late. Before patterning the third metal layer, the second wiring 120 of the semiconductor layer has been ion-doped. Therefore, although the peripheral lead wiring 700 of the third metal layer overlaps the second wiring 120, the ion doping of the second wiring 120 is not affected.

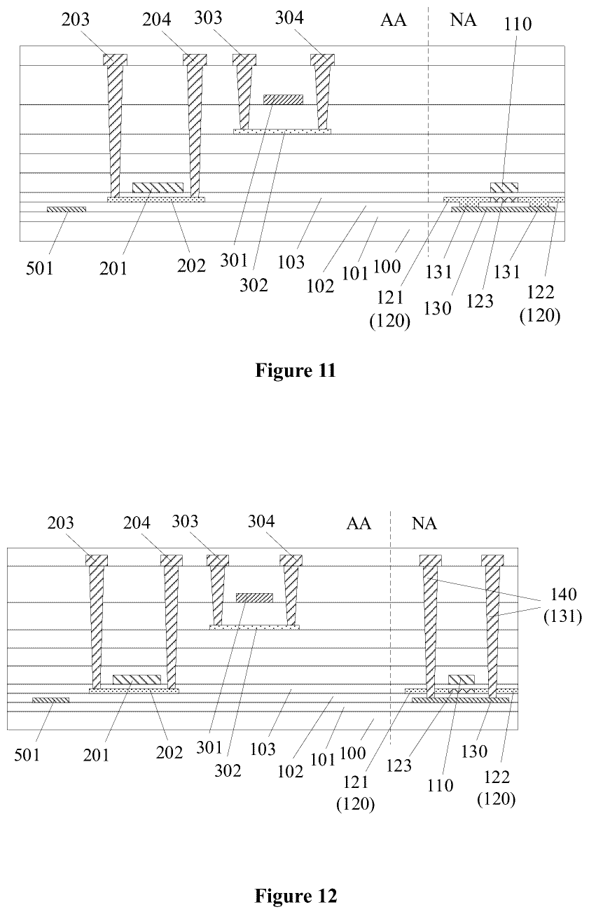

In some embodiments, as shown in FIGS. 11 to 14, the second wiring 120 further includes a third segment 123 connecting the first segment 121 and the second segment 122. The third segment 123 is located on the semiconductor layer. The impedance of the third segment 123 is higher than the impedance of the first segment 121 and the second segment 122. The high impedance of the third segment 123 is actually the state of the second wiring 120 before ion doping. That is, the third segment 123 is a part that is blocked by the first wiring 110 and is not implanted with ions in a case of ion doping the second wiring 120. Since the jumper wiring 130 has been configured to ensure the conductivity of the second wiring 120, the third segment 123 overlapping the first wiring 110 may be retained, or may be regarded as being in a parallel relationship with the jumper wiring 130. The overall conductivity of the second wiring 120 and the jumper 130 may not be affected, a graphic design of the second wiring 120 is simplified.

Reference is made to FIG. 11, in some embodiments, the first segment 121 and the second segment 122 of the second wiring 120 may be directly connected to the jumper wiring 130 based on this structure.

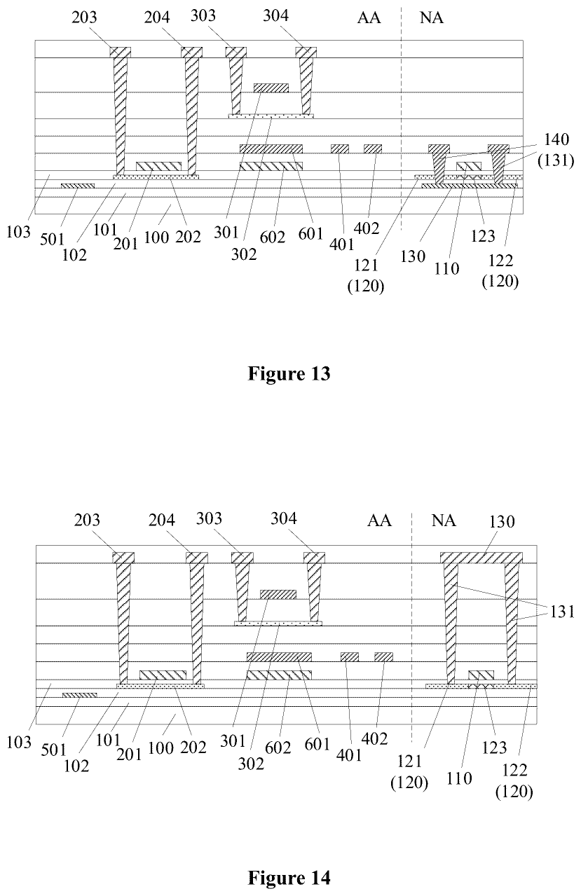

Reference is made to FIGS. 12 and 13, in some embodiments, the first segment 121 and the second segment 122 of the second wiring 120 are connected with the jumper wiring 130 through the jumper columns 140 of other metal layers based on this structure.

Reference is made to FIG. 14, in some embodiments, the first segment 121 and the second segment 122 of the second wiring 120 are connected with jumper wiring 130 in a metal layer above the semiconductor layer based on this structure.

A display device is according to an embodiment of the present disclosure, including the array substrate according to any of above embodiments.

Herein the display device has same features as the array substrate according to the above embodiments, hence it can also solve same problems and achieve same effects.

It should be noted that, the relationship terms such as “first”, “second” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. Therefore, a process, a method, an article or a device including a series of elements include not only the disclosed elements but also other elements that are not clearly enumerated, or further include inherent elements of the process, the method, the article or the device. Unless expressively limited, the statement “including a . . . ” does not exclude the case that other similar elements may exist in the process, the method, the article or the device other than enumerated elements.

1. An array substrate, comprising:
a substrate;
a first metal layer;
a second metal layer; and
a semiconductor layer, wherein
the first metal layer is located on a side of the semiconductor layer away from the substrate;
the first metal layer comprises first wiring, the semiconductor layer comprises second wiring, and the second metal layer comprises jumper wiring;
the array substrate comprises an active area and a non-active area; in the non-active area, the second wiring comprises a first segment and a second segment connected by the jumper wiring, the first segment is located on one side of the first wiring in a first direction, the second segment is located on another side of the first wiring in the first direction, the jumper wiring at least partially overlaps the second wiring in a direction perpendicular to plane in which the array substrate extends.

2. The array substrate according to claim 1, further comprising:
an insulating layer located between the semiconductor layer and the second metal layer, wherein the insulating layer is provided with a via hole, and the second wiring and the jumper wiring are connected through the via hole.

3. The array substrate according to claim 2, further comprising:
a third metal layer, wherein the third metal layer comprises a jumper column filled in the via hole, and the second wiring and the jumper wiring are connected through the jumper column.

4. The array substrate according to claim 3, wherein the active area comprises a pixel circuit, the pixel circuit comprises a transistor, the transistor comprises a source electrode and a drain electrode, and the third metal layer comprises the source electrode or the drain electrode.

5. The array substrate according to claim 3, wherein the active area comprises a pixel circuit, the pixel circuit comprises first power voltage signal wiring and data signal wiring, and the third metal layer comprises: at least one of the first power voltage signal wiring and the data signal wiring.

6. The array substrate according to claim 1, wherein the second metal layer is located between the substrate and the semiconductor layer in a direction perpendicular to the plane in which the array substrate extends.

7. The array substrate according to claim 1, wherein the first metal layer and the semiconductor layer are located between the second metal layer and the substrate.

8. The array substrate according to claim 1, wherein the first metal layer is a gate metal layer.

9. The array substrate according to claim 8, wherein the active area comprises a pixel circuit, the pixel circuit comprises a first transistor, and a first end of the first wiring is electrically connected to a gate electrode of the first transistor; and
the non-active area comprises a first gate driving circuit, and a second end of the first wiring is electrically connected to an output terminal of the first gate driving circuit.

10. The array substrate according to claim 1, wherein the semiconductor layer is a silicon semiconductor layer.

11. The array substrate according to claim 1, wherein the semiconductor layer comprises an electrostatic ring that at least partially surrounds the active area, and the electrostatic ring comprises the second wiring.

12. The array substrate according to claim 11, wherein the non-active area comprises a fillet area, the fillet area has a curved edge, and the fillet area comprises the second wiring.

13. The array substrate according to claim 12, further comprising:
a third metal layer; and
an insulating layer located between the first metal layer and the third metal layer, wherein
the third metal layer is located on a side of the first metal layer away from the semiconductor layer;
the non-active area further comprises a straight-edge area, an edge of the straight-edge area is a straight edge, the straight-edge area comprises a second gate driving circuit and peripheral lead wiring located in the third metal layer, and the first metal layer comprises third wiring;
the active area comprises a pixel circuit, the pixel circuit comprises a second transistor, the third wiring is electrically connected to a gate electrode of the second transistor, and the peripheral lead wiring is connected to the third wiring and the second gate driving circuit;
the insulating layer is provided with a via hole, and the peripheral lead wiring is connected to the third wiring through the via hole; and
the via hole is located on a side of the second wiring close to the active area, and the peripheral lead wiring at least partially overlaps the second wiring in the direction perpendicular to the plane in which the array substrate extends.

14. The array substrate according to claim 6, wherein the array substrate comprises a fingerprint identification area, and the second metal layer comprises a light-shielding pattern formed in the fingerprint identification area.

15. The array substrate according to claim 1, wherein a minimum distance between the first segment and the second segment is greater than a width of the first wiring along the first direction.

16. The array substrate according to claim 15, wherein the width of the first wiring ranges from 2 μm to 3 μm, and the minimum distance between the first segment and the second segment ranges from 4 μm to 6 μm.

17. The array substrate according to claim 1, wherein the second wiring further comprises a third segment connecting the first segment and the second segment, the third segment is located on the semiconductor layer, and an impedance of the third segment is higher than an impedance of the first segment and the second segment.

18. A display device, comprising: an array substrate, wherein the array substrate comprises:
a substrate;
a first metal layer;
a second metal layer; and
a semiconductor layer, wherein
the first metal layer is located on a side of the semiconductor layer away from the substrate;
the first metal layer comprises first wiring, the semiconductor layer comprises second wiring, and the second metal layer comprises jumper wiring;
the array substrate comprises an active area and a non-active area; in the non-active area, the second wiring comprises a first segment and a second segment connected by the jumper wiring, the first segment is located on one side of the first wiring in a first direction, the second segment is located on another side of the first wiring in the first direction, the jumper wiring at least partially overlaps the second wiring in a direction perpendicular to plane in which the array substrate extends.
